(19) United States
(12) Patent Application Publication
(10) Pub. No.: US 2024/0363567 A1
(43) Pub. Date: Oct. 31, 2024

(54) RF ANTENNA MODULE USING COPPER-TO-COPPER INTERCONNECTS BETWEEN THE ANTENNA AND THE RF DIE

(71) Applicant: Intel Corporation, Santa Clara, CA (US)

(72) Inventors: Bernd WAIDHAS, Pettendorf (DE); Thomas WAGNER, Regelsbach (DE); Georg SEIDEMANN, Landshut (DE); Harald GOSSNER, Riemerling (DE); Telesphor KAMGAING, Chandler, AZ (US); Shuhei YAMADA, Vancouver, WA (US); Tae Young YANG, Portland, OR (US)

(21) Appl. No.: 18/140,465

(22) Filed: Apr. 27, 2023

(51) Int. Cl. H01L 23/00; H01Q 1/22; H01Q 1/38

(52) U.S. Cl. CPC H01L 24/08; H01L 24/05; H01Q 1/2283; H01Q 1/38; H01L 24/16; H01L 24/17; H01L 24/29; H01L 24/32; H01L 2224/05647; H01L 2224/08265; H01L 2224/16145; H01L 2224/16225; H01L 2224/17181; H01L 2224/2919; H01L 2224/32013; H01L 2224/32265; H01L 2924/0665

(57) ABSTRACT

Embodiments disclosed herein include a die module. In an embodiment, the die module comprises a die with a first surface and a second surface. In an embodiment, a first pad is on the second surface of the die, where a top surface of the first pad is substantially coplanar with the second surface. In an embodiment, the die module comprises an antenna module with a third surface and a fourth surface. In an embodiment, a second pad is on the third surface of the antenna module, where a bottom surface of the second pad is substantially coplanar with the third surface. In an embodiment, the top surface of the first pad directly contacts the bottom surface of the second pad.

### TECHNICAL FIELD

Embodiments of the present disclosure relate to electronic systems, and more particularly, to electronic packages with discrete antenna modules that are communicatively coupled to an underlying die through copper-to-copper hybrid bonding.

### BACKGROUND

In typical mobile devices, an antenna module comprises a radio frequency (RF) die and overlying antennas, such as patch antennas. The antennas may be fabricated on laminate substrates. The laminate substrates may act as the dielectric material for the antenna as well as the mechanical carrier. The laminate substrate is coupled to the RF die through standard interconnects, such as solder bumps. The antenna dielectric materials may not have a thermo-mechanical match to the RF die. This results in interconnect reliability concerns. For example, warpage of the module may damage the solder interconnects.

In addition to mechanical issues, traditional antenna module systems that use solder interconnects run into electrical issues. For example, the interfaces of different materials along the signal path (e.g., the interface between solder interconnects and copper pads) generate impedance mismatches. This negatively impacts signal transfer between the antenna and the underlying die.

### BRIEF DESCRIPTION OF THE DRAWINGS

FIG. 1 is a cross-sectional illustration of a die module with antenna modules coupled to the die with solder interconnects.

FIG. 2A is a cross-sectional illustration of a die module with antenna modules that are coupled to the die with a hybrid bonding process, in accordance with an embodiment.

FIG. 2B is a cross-sectional illustration of a die module with patch antennas and vertical antennas, in accordance with an embodiment.

FIG. 2C is a cross-sectional illustration of a die module with antenna modules that include both a patch antenna and a vertical antenna, in accordance with an embodiment.

FIG. 2D is a cross-sectional illustration of a die module with antenna modules that include a pair of vertical antennas and a patch antenna, in accordance with an embodiment.

FIG. 3A is a zoomed in illustration of the hybrid bonding interface with copper-to-copper bonds and glass-to-silicon bonds, in accordance with an embodiment.

FIG. 3B is a zoomed in illustration of the hybrid bonding interface with copper-to-copper bonds and insulator-to-silicon bonds, in accordance with an embodiment.

FIG. 3C is a zoomed in illustration of the hybrid bonding interface with copper-to-copper bonds and insulator-to-insulator bonds, in accordance with an embodiment.

FIG. 4 is a cross-sectional illustration of a die module with antenna modules that include an antenna in an overlying buildup layer, in accordance with an embodiment.

FIG. 5A is a cross-sectional illustration of a die module with a digital base die with a pair of RF dies over the base die, and antenna modules over the RF dies, in accordance with an embodiment.

FIG. 5B is a cross-sectional illustration of an electronic system that includes antenna modules coupled to dies with a hybrid bonding process, in accordance with an embodiment.

FIG. 6A is a cross-sectional illustration of a die module that includes an antenna module that is capacitively coupled to a die, in accordance with an embodiment.

FIG. 6B is a zoomed in illustration of the capacitive coupling interface, in accordance with an embodiment.

FIG. 6C is a cross-sectional illustration of a die module with patch antennas and vertical antennas, in accordance with an embodiment.

FIG. 6D is a cross-sectional illustration of a die module with antenna modules that include both a patch antenna and a vertical antenna, in accordance with an embodiment.

FIG. 6E is a cross-sectional illustration of a die module with antenna modules that include a pair of vertical antennas and a patch antenna, in accordance with an embodiment.

FIG. 7A is a cross-sectional illustration of a die module that includes a glass antenna module that is capacitively coupled to a die, in accordance with an embodiment.

FIG. 7B is a zoomed in illustration of the capacitive coupling interface, in accordance with an embodiment.

FIG. 8A is a cross-sectional illustration of a die module that includes an antenna module with an antenna in an overlying buildup layer, in accordance with an embodiment.

FIG. 8B is a cross-sectional illustration of a die module with a continuous dielectric adhesive between a pair of antenna modules and the die, in accordance with an embodiment.

FIG. 9A is a cross-sectional illustration of a die module with antenna modules coupled to a pair of dies that are over an underlying base die, in accordance with an embodiment.

FIG. 9B is a cross-sectional illustration of an electronic system with antenna modules that are capacitively coupled to underlying dies, in accordance with an embodiment.

FIG. 10 is a schematic of a computing device built in accordance with an embodiment.

### EMBODIMENTS OF THE PRESENT DISCLOSURE

Described herein are electronic systems, and more particularly, electronic packages with discrete antenna modules that are communicatively coupled to an underlying die through copper-to-copper hybrid bonding, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

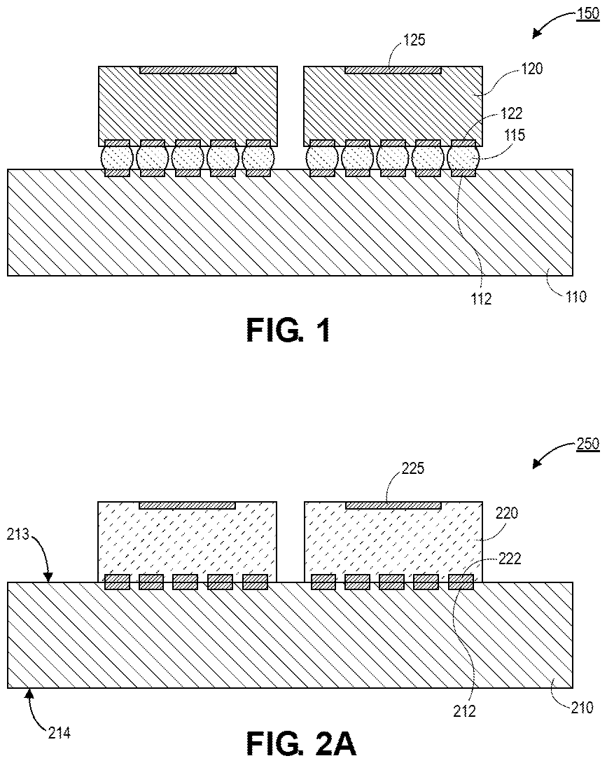

To provide context for embodiments described herein, a die module 150 is shown in FIG. 1. The die module 150 may be a die module 150 for providing wireless communications. For example, the die module 150 may be part of a mobile device or the like. As shown in FIG. 1, the die module 150 may include a base die 110. The base die 110 may be a radio frequency (RF) die. The base die 110 may also comprise a digital domain. The base die 110 may be a silicon die or any other semiconductor material.

Signals are propagated from and received by the antenna modules 120 provided over the base die 110. For example, the antenna modules 120 may include a substrate, such as a dielectric laminate. An antenna 125 may be fabricated into the antenna module 120. The antenna 125 may be coupled to one or more pads 122 at a bottom of the antenna module 120. For example, conductive routing (e.g., pads, traces, vias, etc.) may be provided through the antenna module 120 to couple the antenna 125 to the pads 122.

As shown in FIG. 1, the pads 122 of the antenna module 120 are coupled to pads 112 of the base die 110. For example, interconnects 115, such as solder balls, may be used to couple the pads 112 to the pads 122. The use of solder interconnects 115 results in several issues. One issue is that impedance mismatches may occur along the signal path. This negatively impacts signal transmission. Another issue is that the solder interconnects 115 are difficult to attach as pad 112 and 122 sizes continue to scale down. Additionally, warpage of the antenna module 120 may result in damage to the interconnects 115.

Accordingly, embodiments disclosed herein include alternative coupling architectures that improve reliability and performance of the die module. In one embodiment, the solder interconnects are replaced with a hybrid bonding architecture. In a hybrid bonding process, the copper pads of the base die are directly bonded to the copper pads of the antenna module with a diffusion bonding process. This eliminates an extra interface and allows for copper-to-copper interconnects that do not exhibit an impedance mismatch problem.

In other embodiments, the pads on the base die are communicatively coupled to the pads on the antenna module through the use of capacitive coupling. For example, a dielectric may be provided between the two pads. This results in mechanical decoupling of the base die from the antenna module, which improves mechanical reliability. Additionally, there is no need for a solder reflow process, and processing temperatures may be reduced. Further, there is no X-Y limit regarding further downsizing, and electromigration resilience is increased.

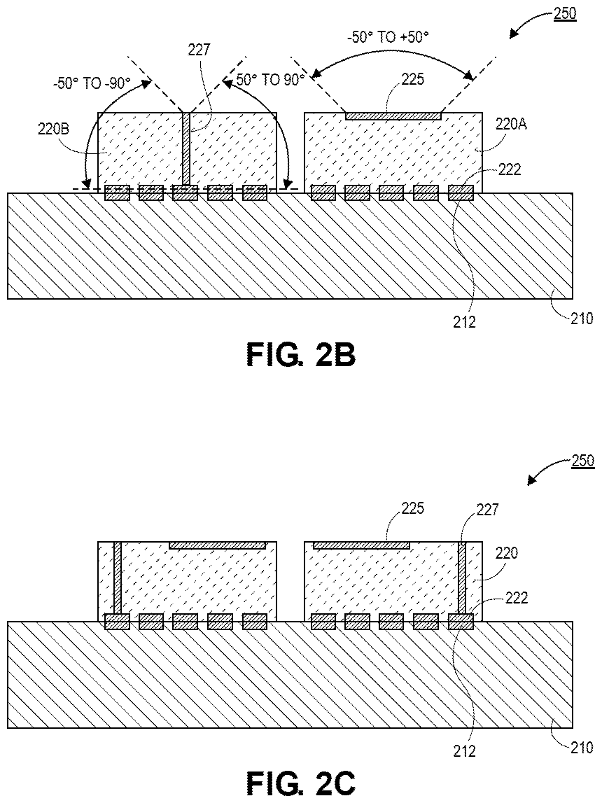

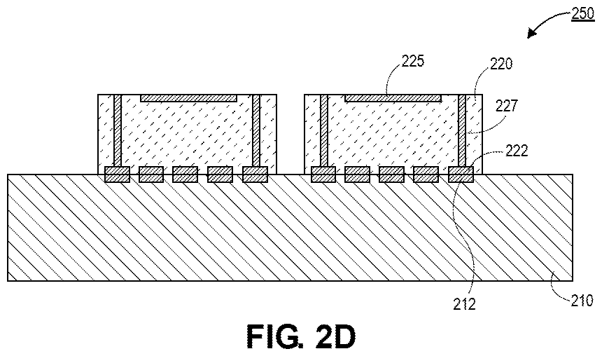

Referring now to FIG. 2A, a cross-sectional illustration of a die module 250 is shown, in accordance with an embodiment. In an embodiment, the die module 250 may comprise a base die 210. The base die 210 may comprise RF functionality. For example, the base die 210 may be configured to receive and transmit high frequency electromagnetic radiation (e.g., in the terahertz range). The base die 210 may also include a digital domain. In the case of a hybrid base die 210, the base die may comprise silicon. Though, it is to be appreciated that the base die 210 may include any suitable semiconductor material or materials. For example, a group III-V semiconductor materials may be useful for the RF domain of the base die 210.

In an embodiment, the base die 210 may include a first surface 214 and a second surface 213 opposite from the first surface 214. The second surface 213 may comprise pads 212. The pads 212 may be recessed into the second surface 213. For example, a top surface of the pads 212 may be substantially coplanar with the second surface 213. The pads 212 may be used to couple an antenna module 220 to the base die 210. While not shown, the first surface 214 may also include pads for coupling to other structures (e.g., a package substrate, another die, or the like). In an embodiment, through silicon vias (TSVs) may also be provided through the thickness of the base die 210. TSVs (not shown) allow for signals from the second surface 213 of the base die 210 to be routed to the first surface 214 of the base die for processing.

In an embodiment, one or more antenna modules 220 may be coupled to the second surface 213 of the base die 210. For example, two antenna modules 220 are shown in FIG. 2A. In an embodiment, the antenna modules 220 may include any suitable substrate. In a particular embodiment, the substrate of the antenna module 220 may be a glass substrate. The use of a glass substrate may allow for improved mechanical reliability since the coefficient of thermal expansion (CTE) of glass is closer to the CTE of silicon or other semiconductor in the base die 210 than an organic laminate film. Glass may also allow for processing at higher temperatures than an organic laminate film. Higher processing temperatures (e.g., approximately 200 degrees Celsius or above) may be used to enable the hybrid bonding operation.

In an embodiment, the antenna module 220 may include an antenna 225. The antenna 225 may be an electrically conductive structure tuned to propagate and/or receive electromagnetic radiation of a particular wavelength or band of wavelengths. In an embodiment, the different antenna modules 220 may be tuned to operate at different wavelengths in order to increase the bandwidth of the die module 250. In an embodiment, the antenna 225 may be fabricated into and/or on the substrate of the antenna module 220. The antenna 225 may be any suitable antenna architecture. In a particular embodiment, the antenna 225 may be a patch antenna.

In an embodiment, the antenna 225 may be communicatively coupled to pads 222 at a bottom of the antenna module 220. For example, conductive features (e.g., pads, traces, vias, etc.) may communicatively couple the antenna 225 to the bottom pads 222.

In an embodiment, the pads 222 may be directly connected to the pads 212 on the second surface 213 of the base die 210. For example, a hybrid bonding process may be used to couple the antenna module 220 to the base die 210. That is, a copper-to-copper bond may be provided between the pads 222 and the pads 212. While a distinct seam is shown in FIG. 2A, it is to be appreciated that diffusion bonding during the hybrid bonding process may occur, and there may not be a seam between pads 222 and pads 212. That is, the bond between the pads 222 and the pads 212 may be considered seamless in some embodiments. The material of the antenna module 220 may also be bonded to the material of the base die 210. As used herein, a hybrid bonded interface may include an interface that comprises at least two different bond types. For example, a first bond type may be a glass-to-silicon die passivation bond and a second bond type may be a copper-to-copper bond.

In an embodiment, additional antenna architectures may also be used in some embodiments. For example, FIGS. 2B-2D provide additional die modules 250 with other antenna configurations.

Referring now to FIG. 2B, a cross-sectional illustration of a die module 250 is shown, in accordance with an embodiment. As shown, a pair of antenna modules 220A and 220B may be provided over a base die 210. The interconnects between the antenna modules 220 and the base die 210 may be similar to those described above with respect to FIG. 2A. In an embodiment, the antenna module 220A may include a patch antenna 225. The field of view for the patch antenna 225 may be from −50° to 50°. On the second antenna module 220B, a vertical antenna 227 may be used. The vertical antenna may have field of views from 50° to 90° as well as from −50° to −90°. Combined the two antenna modules 220A and 220B provide ultra-wide field of view for wireless communications.

Referring now to FIG. 2C, a cross-sectional illustration of a die module 250 is shown in accordance with an additional embodiment. As shown, each antenna module 220 may include a patch antenna 225 and a vertical antenna 227. Similarly, in FIG. 2D, the antenna modules 220 may each include a patch antenna 225 and two or more vertical antennas 227.

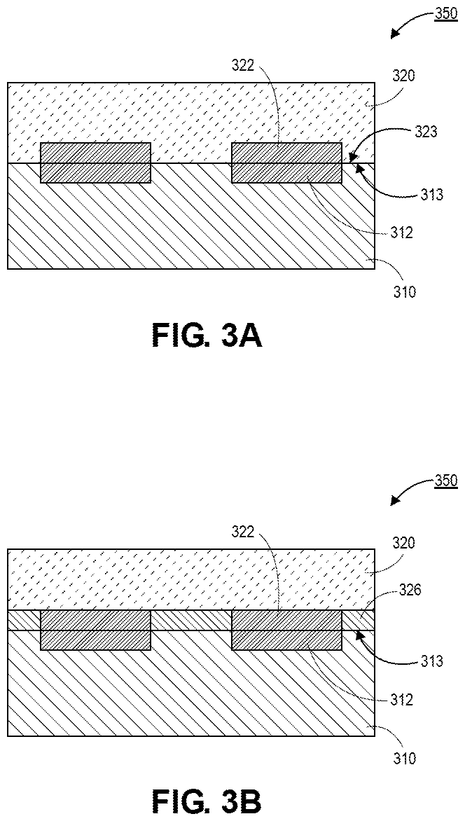

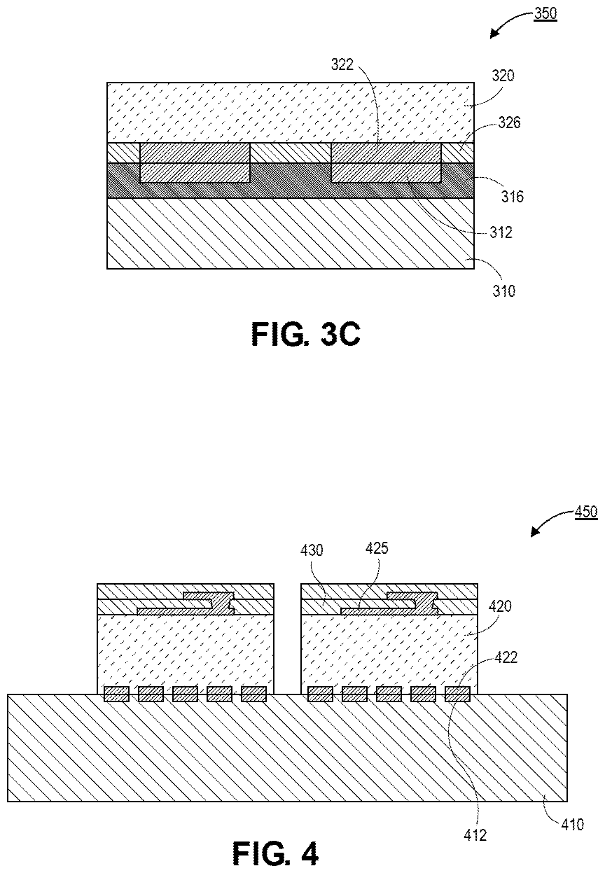

Referring now to FIG. 3A, a zoomed in cross-sectional illustration of the interface between a base die 310 and an antenna module 320 in a die module 350 is shown, in accordance with an additional embodiment. As shown, the pads 322 of the antenna module 320 are directly connected to the pads 312 of the base die 310. While shown as having a perfect alignment, it is to be appreciated that the pads 322 may be misaligned from the pads 312 in an amount up to the alignment tolerance of the hybrid bonding process.

In an embodiment, the pads 322 may be recessed into the antenna module 320. For example, bottom surfaces of the pads 322 may be substantially coplanar with the bottom surface 323 of the antenna module 320. Similarly, the pads 312 may be recessed into the base die 310. For example, top surfaces of the pads 312 may be substantially coplanar with the top surface 313 of the base die 310.

The recessed architecture of the pads 312 and 322 allows for the top surface 313 of the base die 310 to directly contact the bottom surface 323 of the antenna module 320. In one embodiment, the hybrid bond may include copper-to-copper bonds between the pads 312 and 322, as well as glass-to-semiconductor bonds between the bottom surface 323 of the antenna module 320 and the top surface 313 of the base die 310.

Referring now to FIG. 3B, a zoomed in cross-sectional illustration of the hybrid bonding interface between an antenna module 320 and a base die 310 is shown, in accordance with an additional embodiment. The die module 350 in FIG. 3B may be substantially similar to the die module 350 in FIG. 3A, with the exception of the bottom region of the antenna module 320. Instead of having glass through an entire thickness of the antenna module 320, a bottom portion of the antenna module 320 may comprise an insulating layer 326. The insulating layer 326 may be provided around perimeters of the pads 322. For example, a thickness of the insulating layer 326 may be substantially similar to a thickness of the pads 322. However, in other embodiments, the insulating layer 326 may have a thickness that is thicker or thinner than the thickness of the pads 322. In the case of a thicker insulating layer 326, the insulating layer may be provided along sidewalls and a top surface of the pads 322. In an embodiment, the insulating layer 326 may include any suitable insulating material. For example, the insulating layer 326 may comprise silicon and oxygen, silicon, carbon, and nitrogen, an organic film, or the like.

As shown in FIG. 3B, the insulating layer 326 may be directly bonded to the top surface 313 of the underlying base die 310. Accordingly, the hybrid bond may include a copper-to-copper interface between pads 312 and 322, and a semiconductor-to-insulator interface between the insulating layer 326 and the top surface 313 of the base die 310.

Referring now to FIG. 3C, a zoomed in cross-sectional illustration of the hybrid bonding interface of a die module 350 is shown, in accordance with an additional embodiment. The die module 350 in FIG. 3C may be substantially similar to the die module 350 in FIG. 3B, with the exception of the topside of the base die 310. Instead of having semiconductor material through an entire thickness of the base die 310, an insulating layer 316 may be provided along a top of the base die 310. The insulating layer 316 may be any suitable insulating material. For example, the insulating layer 316 may comprise silicon and oxygen, or silicon, carbon, and nitrogen. The insulating layer 316 may have a thickness that is equal to or greater than a thickness of the pads 312. In the illustrated embodiment, the insulating layer 316 is thicker than the pads 312, and the insulating layer 316 wraps around the sidewalls and bottom surface of the pads 312. Though, embodiments may also include an insulating layer 316 that is thinner than the pads 312 in some embodiments.

In such an embodiment, the hybrid bonding interface may include copper-to-copper bonds as well as insulator-to-insulator bonds (i.e., the bond between the insulating layer 316 and the insulating layer 326). While an insulator-to-insulator bond is shown, it is to be appreciated that an insulator-to-glass bond may also be formed. For example, the insulating layer 326 may be omitted, and the insulating layer 316 may be bonded directly to glass of the antenna module 320.

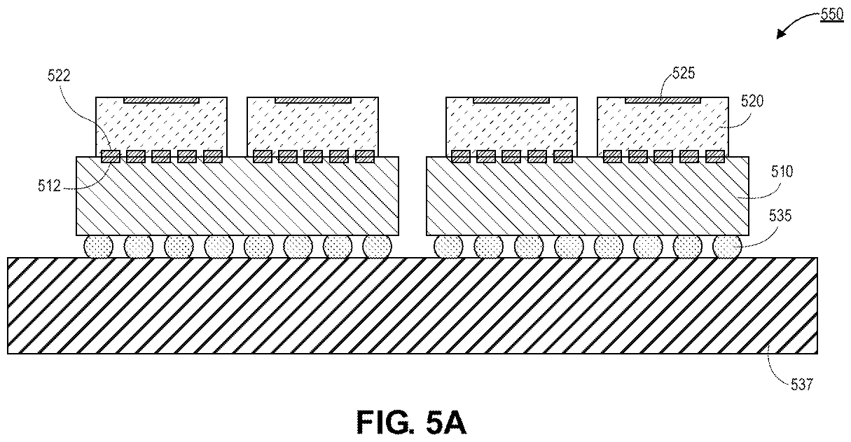

Referring now to FIG. 4, a cross-sectional illustration of a die module 450 is shown, in accordance with an additional embodiment. In an embodiment, the die module 450 may comprise a base die 410. The base die 410 may comprise an RF domain, or an RF domain and a digital domain. The base die 410 may comprise a semiconductor, such as silicon or a group III-V semiconductor material. In an embodiment, pads 412 may be recessed into a top surface of the base die 410.

In an embodiment, the die module 450 may further comprise an antenna module 420. The antenna module 420 may comprise a glass substrate or the like. In an embodiment, the antenna 425 of the antenna module 420 may be fabricated in one or more redistribution layers 430 provided over a top surface of the substrate. The use of redistribution layers 430 may allow for easier patterning and fabrication compared to building the antenna directly in the glass of the substrate. Vias through the glass (not shown) may couple the antenna 425 to the pads 422 at the bottom of the antenna module 420.

In an embodiment, the antenna module 420 may be coupled to the base die 410 using a hybrid bonding approach. For example, the pads 422 may be bonded to the pads 412, and the substrate of the antenna module 420 may be bonded to the base die 410. While shown as a glass-to-semiconductor bond in FIG. 4, it is to be appreciated that insulating layers may also be provided over one or both surfaces of the interface, similar to embodiments described above.

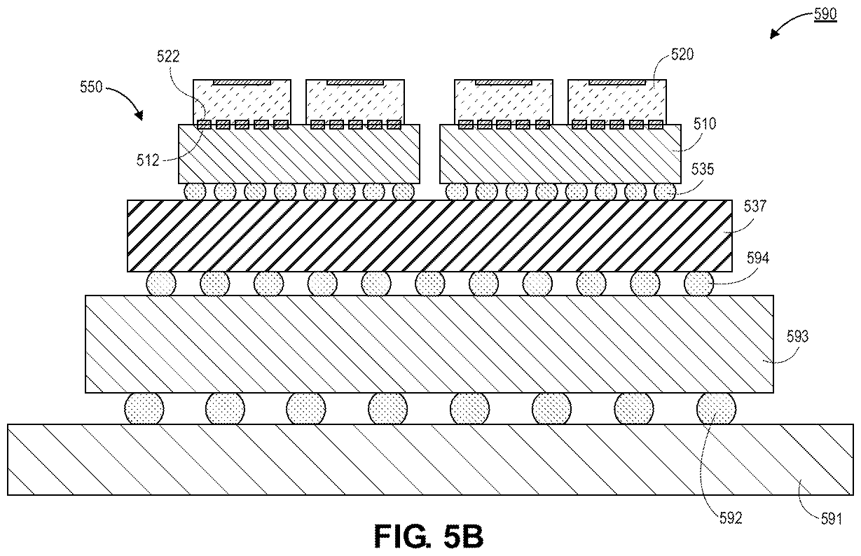

Referring now to FIG. 5A, a cross-sectional illustration of a die module 550 is shown, in accordance with yet another embodiment. In an embodiment, the die module 550 may comprise stacked dies. For example, die 537 may be provided below the dies 510. In such an embodiment, the die 537 may have the digital functionality, and the base dies 510 may have the RF functionality. Bifurcating the digital and RF functionality allows for each die 537 and 510 to be optimized for their given purpose. For example, the digital die 537 may comprise silicon for traditional transistor fabrication, and the RF die 510 may comprise a group III-V semiconductor material. The die 537 may be coupled to the base dies 510 using interconnects 535, such as solder balls or the like.

In an embodiment, antenna modules 520 may be attached to the die 510 using a hybrid bonding approach similar to embodiments described in greater detail above. For example, pads 522 of the antenna modules 520 may be bonded directly to the pads 512 of dies 510. In an embodiment, the antenna modules 520 may comprise a glass substrate. An antenna 525 may be provided at a top surface of the antenna module 520, or in a redistribution layer over the substrate of the antenna module 520.

Referring now to FIG. 5B, a cross-sectional illustration of an electronic system 590 is shown, in accordance with an embodiment. In an embodiment, the electronic system 590 may comprise a board 591, such as a printed circuit board (PCB). The board 591 may be coupled to a package substrate 593 by interconnects 592. The interconnects 592 may be solder balls, sockets, or any other suitable interconnect architecture.

In an embodiment, the die module 550 may be coupled to the package substrate 593 by interconnects 594, such as solder balls or the like. In some embodiments, the die module 550 may be directly coupled to the board 591 without an intervening package substrate 593.

In an embodiment, the die module 550 may be similar to any of the die modules described in greater detail herein. For example, a die module 550 may be similar to the die module 550 in FIG. 5A is shown as one potential embodiment. As shown, a die 537, such as a digital die, is coupled to one or more RF dies 510 by interconnects 535. In an embodiment, antenna modules 520 are coupled to the RF dies 510 through a hybrid bonding process. For example, pads 522 in the antenna module 520 are directly coupled to pads 512 in the RF dies 510.

While embodiments described above include hybrid bonding architectures, embodiments are not limited to such configurations. For example, alternative communicative coupling approaches may be used to couple the antenna module to an underlying base die without the use of a solder interconnect. In the embodiments described in greater detail below, a capacitive coupling configuration is provided. That is, pads in the antenna module are communicatively coupled to pads in the underlying die by a capacitance. Accordingly, a dielectric layer may be provided between the pads to induce the capacitive response.

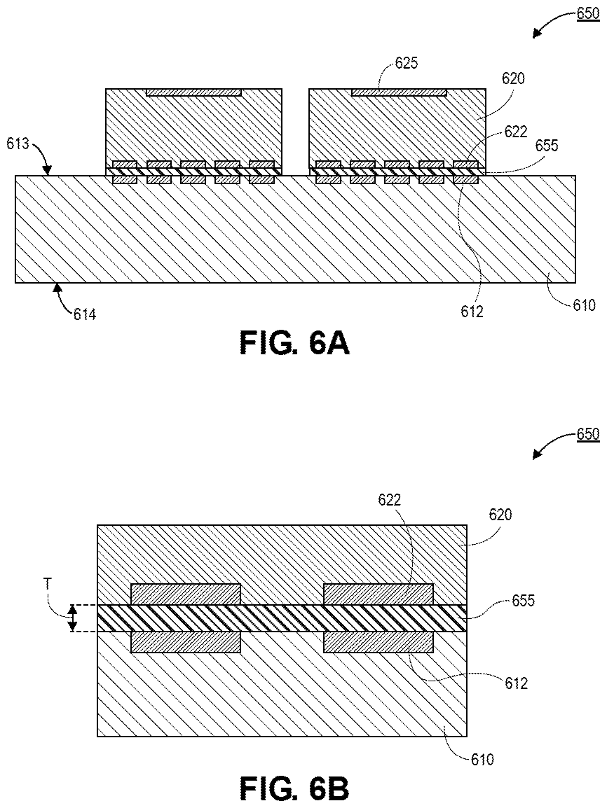

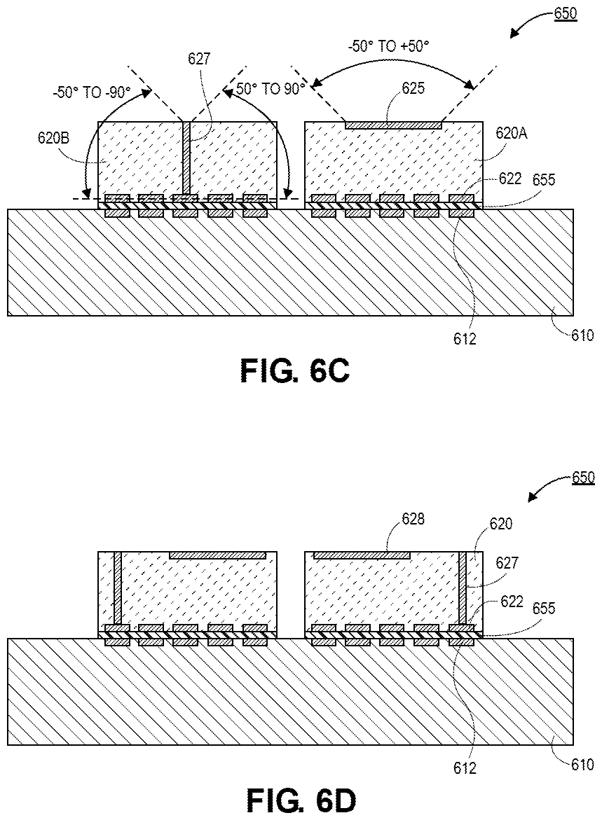

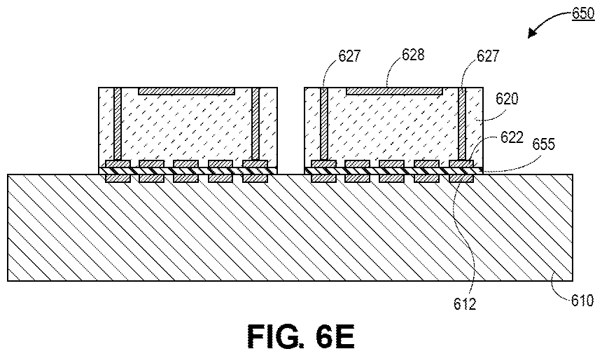

Referring now to FIG. 6A a cross-sectional illustration of a die module 650 is shown, in accordance with an embodiment. In an embodiment, the die module 650 may comprise a base die 610. The base die 610 may comprise RF functionality. For example, the base die 610 may be configured to receive and transmit high frequency electromagnetic radiation (e.g., in the terahertz range). The base die 610 may also include a digital domain. In the case of a hybrid base die 610, the base die may comprise silicon.

Though, it is to be appreciated that the base die 610 may include any suitable semiconductor material or materials. For example, a group III-V semiconductor materials may be useful for the RF domain of the base die 610.

In an embodiment, the base die 610 may include a first surface 614 and a second surface 613 opposite from the first surface 614. The second surface 613 may comprise pads 612. The pads 612 may be recessed into the second surface 613. For example, a top surface of the pads 612 may be substantially coplanar with the second surface 613. The pads 612 may be used to couple an antenna module 620 to the base die 610. While not shown, the first surface 614 may also include pads for coupling to other structures (e.g., a package substrate, another die, or the like). In an embodiment, TSVs may also be provided through the thickness of the base die 610. TSVs (not shown) allow for signals from the second surface 613 of the base die 610 to be routed to the first surface 614 of the base die for processing.

In an embodiment, one or more antenna modules 620 may be coupled to the second surface 613 of the base die 610. For example, two antenna modules 620 are shown in FIG. 6A. In an embodiment, the antenna modules 620 may include any suitable substrate. In the particular embodiment shown in FIG. 6A, the antenna modules 620 comprise organic buildup film layers.

In an embodiment, the antenna module 620 may include an antenna 625. The antenna 625 may be an electrically conductive structure tuned to propagate and/or receive electromagnetic radiation of a particular wavelength or band of wavelengths. In an embodiment, the different antenna modules 620 may be tuned to operate at different wavelengths in order to increase the bandwidth of the die module 650. In an embodiment, the antenna 625 may be fabricated into and/or on the substrate of the antenna module 620. The antenna 625 may be any suitable antenna architecture. In a particular embodiment, the antenna 625 may be a patch antenna.

In an embodiment, the antenna 625 may be communicatively coupled to pads 622 at a bottom of the antenna module 620. For example, conductive features (e.g., pads, traces, vias, etc.) may communicatively couple the antenna 625 to the bottom pads 622.

In an embodiment, the pads 622 may be capacitively coupled to the pads 612 on the second surface 613 of the base die 610. A dielectric layer 655 may be provided between the pads 622 and the pads 612 to aid in the capacitive coupling. The dielectric layer 655 may also be an adhesive in order to mechanically secure the antenna module 620 to the base die 610. For example, the dielectric layer 655 may be an epoxy or the like.

The capacitive coupling between the base die 610 and the antenna module 620 eliminates the solder interconnects 115 between the base die 110 and the antenna module 120 as shown in FIG. 1. This may limit the lifetime of the module by solder joint fatigue by thermo-mechanical stress and strain. An appropriate dielectric material 655 may improve the reliability of the module. Additionally, there is no need for a solder reflow process, and processing temperatures may be reduced. Further, electromigration resilience may be increased when capacitive coupling is used, because no soldering flux is required for the interconnection process.

Referring now to FIG. 6B, a zoomed in illustration of a die module 650 of the capacitive coupling feature between the antenna module 620 and the base die 610 is shown, in accordance with an embodiment. As shown, the dielectric layer 655 provides a spacing between the pads 622 and the pads 612. That is, the pads 622 are not electrically connected to the pads 612 by an external interconnect, such as a solder. Additionally, the pads 622 do not directly contact the pads 612, similar to embodiments described above with respect to the hybrid bonding architectures. In an embodiment, the dielectric layer 655 may have any suitable thickness T. For example, the dielectric layer 655 may have a thickness T that is up to approximately 10 μm. Though, larger thicknesses T may also be used in some embodiments.

In an embodiment, the dielectric layer 655 may only contact the bottom surface of the pads 622 and the top surface of the pads 612. This is because the pads 622 may be recessed into the substrate of the antenna module 620, and the pads 612 may be recessed into the surface of the base die 610. Though, in some embodiments, the pads 622 and/or 612 may protrude out. In such instances, the dielectric layer 655 may contact portions, or the entirety, of the sidewalls of the pads 622 and 612.

In an embodiment, additional antenna architectures may also be used in some embodiments. For example, FIGS. 6C-6E provide additional die modules 650 with other antenna configurations.

Referring now to FIG. 6C, a cross-sectional illustration of a die module 650 is shown, in accordance with an embodiment. As shown, a pair of antenna modules 620A and 620B may be provided over a base die 610. The interconnects between the antenna modules 620 and the base die 610 may be similar to those described above with respect to FIG. 6A. In an embodiment, the antenna module 620A may include a patch antenna 625. The field of view for the patch antenna 625 may be from −50° to 50°. On the second antenna module 620B, a vertical antenna 627 may be used. The vertical antenna may have field of views from 50° to 90° as well as from −50° to −90°. Combined the two antenna modules 620A and 620B provide ultra-wide field of view for wireless communications.

Referring now to FIG. 6D, a cross-sectional illustration of a die module 650 is shown in accordance with an additional embodiment. As shown, each antenna module 620 may include a patch antenna 625 and a vertical antenna 627. Similarly, in FIG. 6E, the antenna modules 620 may each include a patch antenna 625 and two or more vertical antennas 627.

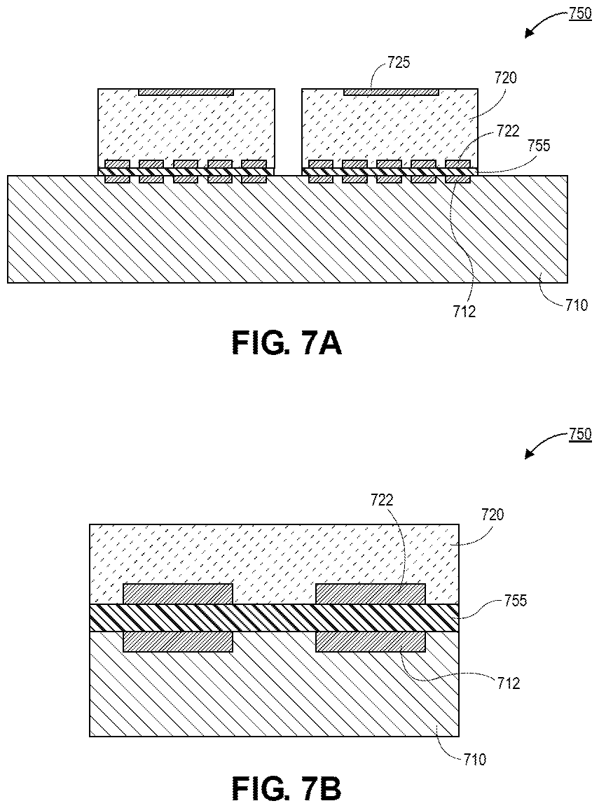

Referring now to FIG. 7A, a cross-sectional illustration of a die module 750 is shown, in accordance with an additional embodiment. In an embodiment, the die module 750 in FIG. 7A may be substantially similar to the die module 650 in FIG. 6A, with the exception of the material for the substrate of the antenna module 720. Instead of using organic layers, the antenna module 720 may include a glass substrate. The pads 712 of the base die 710 are capacitively coupled to the pads 722 of the antenna module 720 across a dielectric layer 755. The antenna 725 may also be provided directly into the glass substrate at the top of the antenna module 720.

Referring now to FIG. 7B, a zoomed in illustration of a die module 750 of the capacitive coupling feature between the antenna module 720 and the base die 710 is shown, in accordance with an embodiment. As shown, the dielectric layer 755 provides a spacing between the pads 722 and the pads 712. That is, the pads 722 are not electrically connected to the pads 712 by an external interconnect, such as a solder. Additionally, the pads 722 do not directly contact the pads 712, similar to embodiments described above with respect to the hybrid bonding architectures. In an embodiment, the dielectric layer 755 may have any suitable thickness. For example, the dielectric layer 755 may have a thickness up to approximately 10 μm or thicker.

In an embodiment, the dielectric layer 755 may only contact the bottom surface of the pads 722 and the top surface of the pads 712. This is because the pads 722 may be recessed into the substrate of the antenna module 720, and the pads 712 may be recessed into the surface of the base die 710. Though, in some embodiments, the pads 722 and/or 712 may protrude out. In such instances, the dielectric layer 755 may contact portions, or the entirety, of the sidewalls of the pads 722 and 712.

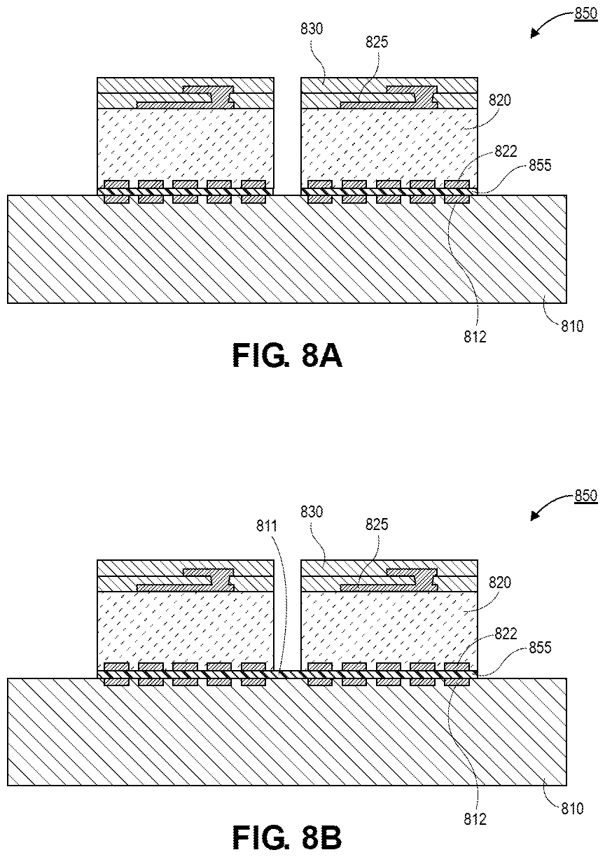

Referring now to FIG. 8A, a cross-sectional illustration of a die module 850 is shown, in accordance with an additional embodiment. In an embodiment, the die module 850 comprises a base die 810. The base die 810 may include pads 812. The pads 812 may be communicatively coupled with pads 822 of an antenna module 820. Particularly, a dielectric layer 855 may be provided between the pads 822 and the pads 812 in order to enable capacitive coupling between the pads 822 and 812.

In an embodiment, the antenna module 820 may further comprise an antenna 825 that is provided over the top surface of the substrate (e.g., a glass substrate). The antenna 825 may be fabricated in one or more redistribution layers 830. The redistribution layers 830 may allow for easier patterning and fabrication of the antenna 825 compared to embodiments where the antenna 825 is fabricated in the substrate of the antenna module 820.

Referring now to FIG. 8B, a cross-sectional illustration of a die module 850 is shown, in accordance with an additional embodiment. The die module 850 may be similar to any of the capacitively coupled die modules described above, with the exception of the dielectric layer 855. Instead of having discrete dielectric layers 855 below each of the antenna modules 820, a single dielectric layer 855 is provided along the surface of the base die 810. For example, portions 811 of the dielectric layer 855 may be provided between a pair of antenna modules 820. That is, width and length dimensions of the dielectric layer 855 may be larger than width and length dimensions of the antenna modules 820. Further, a single dielectric layer 855 may be provided below two or more antenna modules 820.

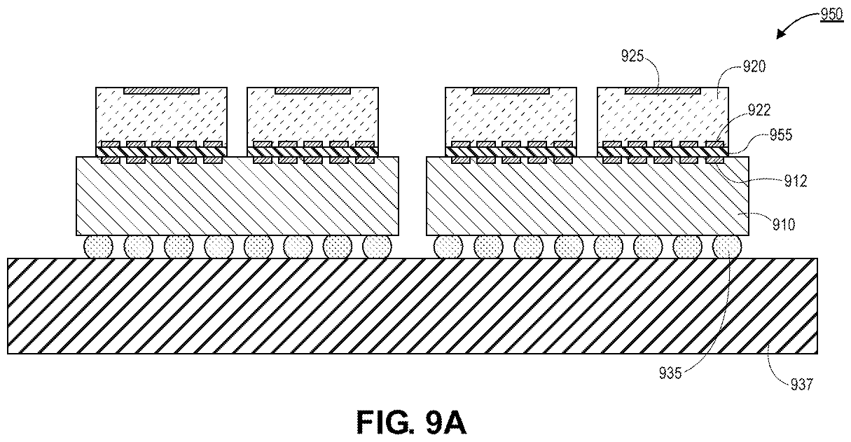

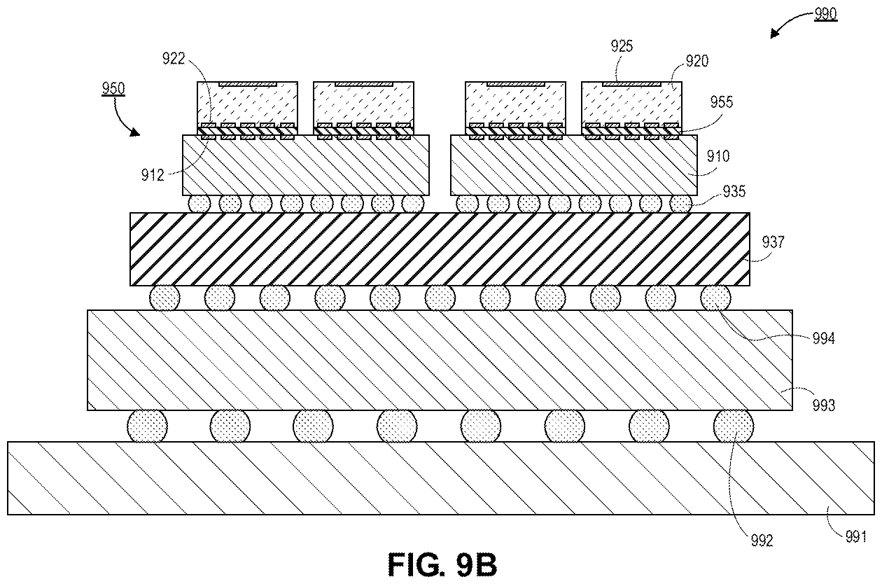

Referring now to FIG. 9A, a cross-sectional illustration of a die module 950 is shown, in accordance with yet another embodiment. In an embodiment, the die module 950 may comprise stacked dies. For example, die 937 may be provided below the dies 910. In such an embodiment, the die 937 may have the digital functionality, and the base dies 910 may have the RF functionality. Bifurcating the digital and RF functionality allows for each die 937 and 910 to be optimized for their given purpose. For example, the digital die 937 may comprise silicon for traditional transistor fabrication, and the RF die 910 may comprise a group III-V semiconductor material. The die 937 may be coupled to the base dies 910 using interconnects 935, such as solder balls or the like.

In an embodiment, antenna modules 920 may be attached to the die 910 using a capacitive coupling architecture similar to embodiments described in greater detail above. For example, pads 922 of the antenna modules 920 may be spaced apart from the pads 912 of dies 910 by a dielectric layer 955. The dielectric layer 955 may be a dielectric adhesive, such as an epoxy or the like. In an embodiment, the antenna modules 920 may comprise a glass substrate. Though, organic substrates may also be used in some embodiments. An antenna 925 may be provided at a top surface of the antenna module 920, or in a redistribution layer over the substrate of the antenna module 920.

Referring now to FIG. 9B, a cross-sectional illustration of an electronic system 990 is shown, in accordance with an embodiment. In an embodiment, the electronic system 990 may comprise a board 991, such as a PCB. The board 991 may be coupled to a package substrate 993 by interconnects 992. The interconnects 992 may be solder balls, sockets, or any other suitable interconnect architecture.

In an embodiment, the die module 950 may be coupled to the package substrate 993 by interconnects 994, such as solder balls or the like. In some embodiments, the die module 950 may be directly coupled to the board 991 without an intervening package substrate 993.

In an embodiment, the die module 950 may be similar to any of the die modules with capacitively coupled pads described in greater detail herein. For example, a die module 950 may be similar to the die module 950 in FIG. 9A is shown as one potential embodiment. As shown, a die 937, such as a digital die, is coupled to one or more RF dies 910 by interconnects 935. In an embodiment, antenna modules 920 are coupled to the RF dies 910 through a capacitive coupling process. For example, pads 922 in the antenna module 920 may be separated from the pads 912 in the RF dies 910 by a dielectric layer 955. The dielectric layer 955 may be an adhesive dielectric layer, such as an epoxy or the like.

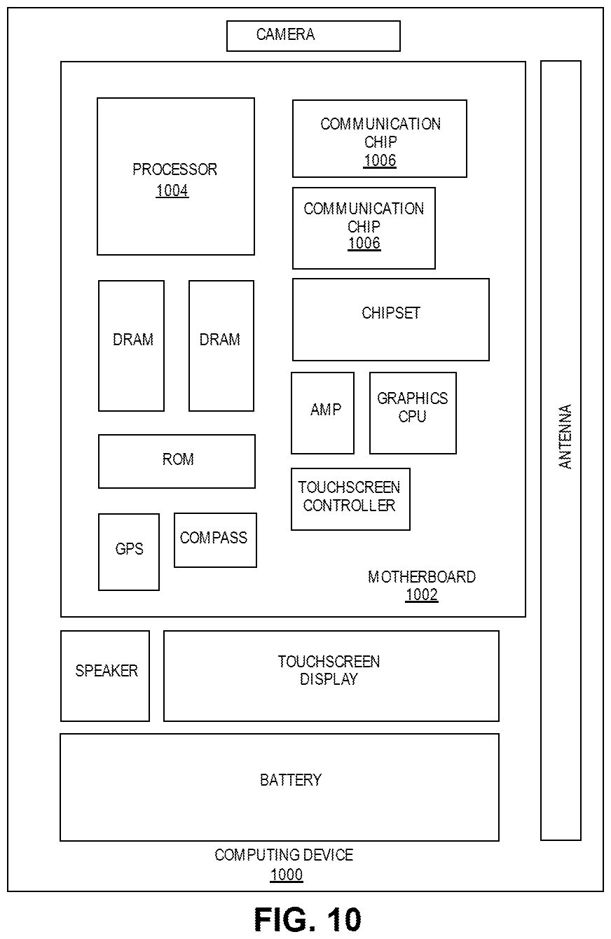

FIG. 10 illustrates a computing device 1000 in accordance with one implementation of the invention. The computing device 1000 houses a board 1002. The board 1002 may include a number of components, including but not limited to a processor 1004 and at least one communication chip 1006. The processor 1004 is physically and electrically coupled to the board 1002. In some implementations the at least one communication chip 1006 is also physically and electrically coupled to the board 1002. In further implementations, the communication chip 1006 is part of the processor 1004.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1006 enables wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing device 1000 includes an integrated circuit die packaged within the processor 1004. In some implementations of the invention, the integrated circuit die of the processor may be part of an electronic system with an antenna module that is coupled to an underlying die with a hybrid bonding interface or through capacitive coupling, in accordance with embodiments described herein. The term “processor” may refer to any device or portion of a device that processes electronic data from registers and/or memory to transform that electronic data into other electronic data that may be stored in registers and/or memory.

The communication chip 1006 also includes an integrated circuit die packaged within the communication chip 1006. In accordance with another implementation of the invention, the integrated circuit die of the communication chip may be part of an electronic system with an antenna module that is coupled to an underlying die with a hybrid bonding interface or through capacitive coupling, in accordance with embodiments described herein.

In an embodiment, the computing device 1000 may be part of any apparatus. For example, the computing device may be part of a personal computer, a server, a mobile device, a tablet, an automobile, or the like. That is, the computing device 1000 is not limited to being used for any particular type of system, and the computing device 1000 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a die module, comprising: a die with a first surface and a second surface; a first pad on the second surface of the die, wherein a top surface of the first pad is substantially coplanar with the second surface; an antenna module with a third surface and a fourth surface; a second pad on the third surface of the antenna module, wherein a bottom surface of the second pad is substantially coplanar with the third surface, and wherein the top surface of the first pad directly contacts the bottom surface of the second pad.

Example 2: the die module of Example 1, wherein the second surface of the die is bonded to the third surface of the antenna module.

Example 3: the die module of Example 2, wherein the third surface of the antenna module comprises a glass material, and wherein the second surface of the die comprises an insulator.

Example 4: the die module of Example 3, wherein the insulator comprises a material comprising nitrogen, carbon, and silicon, or a material comprising oxygen and silicon.

Example 5: the die module of Examples 1-4, wherein the antenna module comprises a glass substrate.

Example 6: the die module of Examples 1-5, wherein an interface between the first pad and the second pad is seamless.

Example 7: the die module of Example 6, wherein the first pad is diffusion bonded to the second pad.

Example 8: the die module of Examples 1-3, wherein the antenna module comprises a patch antenna, a vertical antenna, or a patch antenna and a vertical antenna.

Example 9: the die module of Examples 1-8, wherein a redistribution layer is provided over the antenna module, and wherein an antenna is provided in the redistribution layer.

Example 10: the die module of Examples 1-9, wherein the die is a radio frequency (RF) die.

Example 11: the die module of Example 10, wherein the die comprises a group III-V semiconductor.

Example 12: a communications module, comprising: a die with first pads; and an antenna module with second pads, wherein individual ones of the first pads are directly contacting individual ones of the second pads.

Example 13: the communications module of Example 12, wherein the first pads and the second pads comprise copper.

Example 14: the communications module of Example 12 or Example 13, wherein the first pads are diffusion bonded to the second pads.

Example 15: the communications module of Examples 12-14, wherein the die is hybrid bonded to the antenna module.

Example 16: the communications module of Examples 12-15, wherein the antenna module comprises a glass substrate.

Example 17: the communications module of claim 16, wherein a redistribution layer is provided on the glass substrate, and wherein an antenna is provided in the redistribution layer.

Example 18: an electronic system, comprising: a board; a package substrate coupled to the board; and a die module coupled to the package substrate, wherein the die module comprises: a die with first pads; and an antenna module with second pads, and wherein the die is hybrid bonded to the antenna module so that the first pads are bonded directly to the second pads.

Example 19: the electronic system of Example 18, wherein the antenna module comprises a glass substrate.

Example 20: the electronic system of Example 18 or Example 19, wherein the electronic system is part of a personal computer, a server, a mobile device, a tablet, or an automobile.

What is claimed is:

1. A die module, comprising:
a die with a first surface and a second surface;
a first pad on the second surface of the die, wherein a top surface of the first pad is substantially coplanar with the second surface;
an antenna module with a third surface and a fourth surface;
a second pad on the third surface of the antenna module, wherein a bottom surface of the second pad is substantially coplanar with the third surface, and wherein the top surface of the first pad directly contacts the bottom surface of the second pad.

2. The die module of claim 1, wherein the second surface of the die is bonded to the third surface of the antenna module.

3. The die module of claim 2, wherein the third surface of the antenna module comprises a glass material, and wherein the second surface of the die comprises an insulator.

4. The die module of claim 3, wherein the insulator comprises a material comprising nitrogen, carbon, and silicon, or a material comprising oxygen and silicon.

5. The die module of claim 1, wherein the antenna module comprises a glass substrate.

6. The die module of claim 1, wherein an interface between the first pad and the second pad is seamless.

7. The die module of claim 6, wherein the first pad is diffusion bonded to the second pad.

8. The die module of claim 1, wherein the antenna module comprises a patch antenna, a vertical antenna, or a patch antenna and a vertical antenna.

9. The die module of claim 1, wherein a redistribution layer is provided over the antenna module, and wherein an antenna is provided in the redistribution layer.

10. The die module of claim 1, wherein the die is a radio frequency (RF) die.

11. The die module of claim 10, wherein the die comprises a group III-V semiconductor.

12. A communications module, comprising:
a die with first pads; and
an antenna module with second pads, wherein individual ones of the first pads are directly contacting individual ones of the second pads.

13. The communications module of claim 12, wherein the first pads and the second pads comprise copper.

14. The communications module of claim 12, wherein the first pads are diffusion bonded to the second pads.

15. The communications module of claim 12, wherein the die is hybrid bonded to the antenna module.

16. The communications module of claim 12, wherein the antenna module comprises a glass substrate.

17. The communications module of claim 16, wherein a redistribution layer is provided on the glass substrate, and wherein an antenna is provided in the redistribution layer.

18. An electronic system, comprising:
a board;
a package substrate coupled to the board; and
a die module coupled to the package substrate, wherein the die module comprises:
a die with first pads; and
an antenna module with second pads, and wherein the die is hybrid bonded to the antenna module so that the first pads are bonded directly to the second pads.

19. The electronic system of claim 18, wherein the antenna module comprises a glass substrate.

20. The electronic system of claim 18, wherein the electronic system is part of a personal computer, a server, a mobile device, a tablet, or an automobile.
